(19) United States
(12) Patent Application Publication
(10) Pub. No.: US 2020/0161198 A1
(43) Pub. Date: May 21, 2020

(54) TEST PATTERN GROUP AND SEMICONDUCTOR DEVICE INCLUDING THE SAME

(71) Applicant: Samsung Electronics Co., Ltd., Suwon-si (KR)

(72) Inventors: Byung-jae Park, Seongnam-si (KR); Ju-hyun Kim, Suwon-si (KR)

(73) Assignee: Samsung Electronics Co., Ltd., Suwon-si (KR)

(21) Appl. No.: 16/383,815

(22) Filed: Apr. 15, 2019

(30) Foreign Application Priority Data
Nov. 15, 2018 (KR) 10-2018-0141139

(51) Int. Cl. H01L 21/66; H01L 27/088; H01L 29/78

(52) U.S. Cl. CPC H01L 22/34; H01L 29/7851; H01L 27/0886

(57) ABSTRACT

A test pattern group includes a plurality of test patterns. Each of the plurality of test patterns includes a substrate including a first region and a second region, a first fin group and a second fin group each including fins extending on the first region of the substrate and the second region of the substrate. a first gate structure and a second gate structure each positioned on the first fin group and formed to intersect with the fins of the first fin group and the second fin group, a first source/drain contact formed on a first source/drain, a second source/drain contact formed on a second source/drain, a first gate contact formed on the first gate structure, and a second gate contact formed on the second gate structure. The number of fins included in the first fin group is greater than the number of fins included in the second fin group.

### CROSS-REFERENCE TO RELATED APPLICATION

This application claims the benefit of Korean Patent Application No. 10-2018-0141139, filed on Nov. 15, 2018, in the Korean Intellectual Property Office, the disclosure of which is incorporated herein in its entirety by reference.

### BACKGROUND

Example embodiments of the inventive concepts relate to a test pattern group and/or a semiconductor device including the same.

As semiconductor devices tend to be highly integrated, alignment, isolation, and electrical connection between components of the semiconductor devices remarkably affect yields of the semiconductor devices. Therefore, in processes of manufacturing a semiconductor device, it may be desirable to design a test pattern group for testing whether the components of the semiconductor device are formed and operate.

### SUMMARY

Example embodiments of the inventive concepts provide a test pattern group for performing an electrical test in order to inhibit (or, alternatively, prevent) an electrical short from being generated between a parasitic fin that remains by not being removed in a fin cutting process and contacts of semiconductor devices, and/or a semiconductor device including the same.

According to an example embodiment of the inventive concepts, there is provided a test pattern group including a test pattern group including a plurality of test patterns, each of the plurality of test patterns including, a substrate including a first region and a second region, a first fin group including first fins extending on the first region of the substrate, a second fin group including second fins extending on the second region of the substrate, a number of the second fins of the second fin group less than a number of first fins of the first fin group, a first gate structure on the first fin group such that the first gate structure intersects the first fins of the first fin group, a second gate structure on the second fin group such that the second gate structure intersects the second fins of the second fin group, a first source/drain at a side portion of the first gate structure, a second source/drain at a side portion of the second gate structure, a first source/drain contact on the first source/drain, a second source/drain contact on the second source/drain, a first gate contact on the first gate structure, and a second gate contact on the second gate structure.

According to an example embodiment of the inventive concepts, there is provided a test pattern group including a plurality of test patterns, each of the plurality of test patterns including a firs test pattern and a second test pattern. The first test pattern including a substrate including a first region and a second region, a first fin group including first fins extending on the first region of the substrate, a second fin group including second fins that extend on the second region of the substrate, a number of the second fins of the second fin group less than a number of the first fins of the first fin group, and the second fins of the second fin group electrically disconnected from the first fins of the first fin group, a first gate structure on the first fin group such that the first gate structure intersects the first fins of the first fin group, a second gate structure on the second fin group such that the second gate structure intersects the second fins of the second fin group, a first source/drain at a side portion of the first gate structure, a second source/drain at a side portion of the second gate structure, a first source/drain contact on the first source/drain, a second source/drain contact on the second source/drain, a first gate contact on the first gate structure, and a second gate contact on the second gate structure. The second test pattern being under the first test pattern, the second test pattern including, a third fin group including third fins extending on the substrate, a third gate structure on the third fin group such that the third gate structure intersects with the third fins of the third fin group, a third source/drain at a side portion of the third gate structure, and a third source/drain contact on the third source/drain.

According to an example embodiment of the inventive concepts, there is provided a semiconductor device including

### BRIEF DESCRIPTION OF THE DRAWINGS

Example embodiments of the inventive concepts will be more clearly understood from the following detailed description taken in conjunction with the accompanying drawings in which:

FIGS. 1 to 4B are views illustrating processes of forming a semiconductor device on a substrate;

FIG. 5 is a view illustrating a semiconductor device in which semiconductor devices are integrated according to an example embodiment of the inventive concepts;

FIG. 6 is a view illustrating an enlargement of the region A of FIG. 5;

FIG. 7 is a plan view illustrating an enlargement of a test pattern group according to example embodiments of the inventive concepts;

FIG. 8 is a perspective view illustrating a test pattern according to an example embodiment of the inventive concepts;

FIG. 9 is a cross-sectional view taken along the line A-A of FIG. 8 of the test pattern according to an example embodiment of the inventive concepts;

FIG. 10A is a cross-sectional view taken along the line B-B of FIG. 8 of the test pattern according to an example embodiment of the inventive concepts;

FIG. 10B is a cross-sectional view taken along the line C-C of FIG. 8 of the test pattern according to an example embodiment of the inventive concepts;

FIG. 11 is a perspective view of the test pattern according to an example embodiment of the inventive concepts;

FIG. 12 is a plan view of the test pattern according to an example embodiment of the inventive concepts;

FIG. 13 is a plan view of a test pattern group including the plurality of test patterns according to an example embodiment of the inventive concepts;

FIG. 14 is a plan view of a test pattern according to an example embodiment of the inventive concepts;

FIG. 15 is a perspective view of a test pattern according to an example embodiment of the inventive concepts;

FIG. 16 is a plan view of the test pattern according to an example embodiment of the inventive concepts;

FIG. 17 is a plan view of a test pattern group including the plurality of test patterns according to an example embodiment of the inventive concepts;

FIG. 18 is a perspective view of a test pattern according to an example embodiment of the inventive concepts;

FIG. 19 is a plan view of the test pattern according to an example embodiment of the inventive concepts;

FIG. 20 is a plan view of a test pattern group including the plurality of test patterns according to an example embodiment of the inventive concepts; and

FIG. 21 is a view illustrating a semiconductor device including a test pattern according to an example embodiment of the inventive concepts.

### DETAILED DESCRIPTION

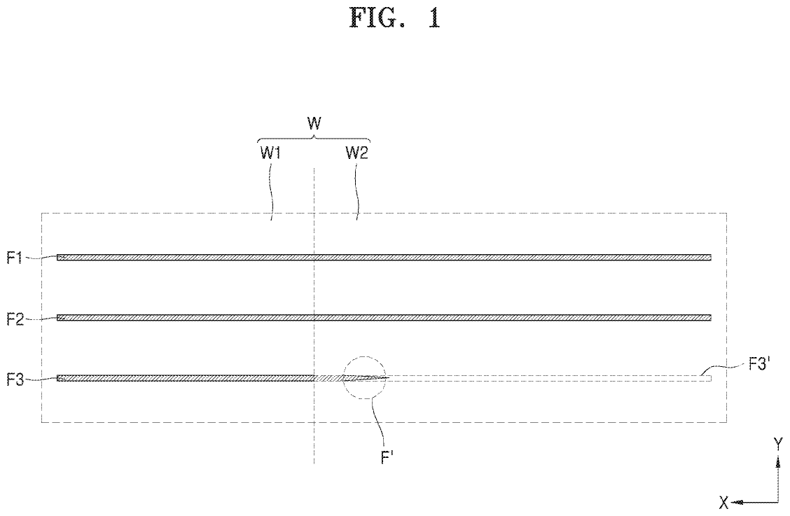

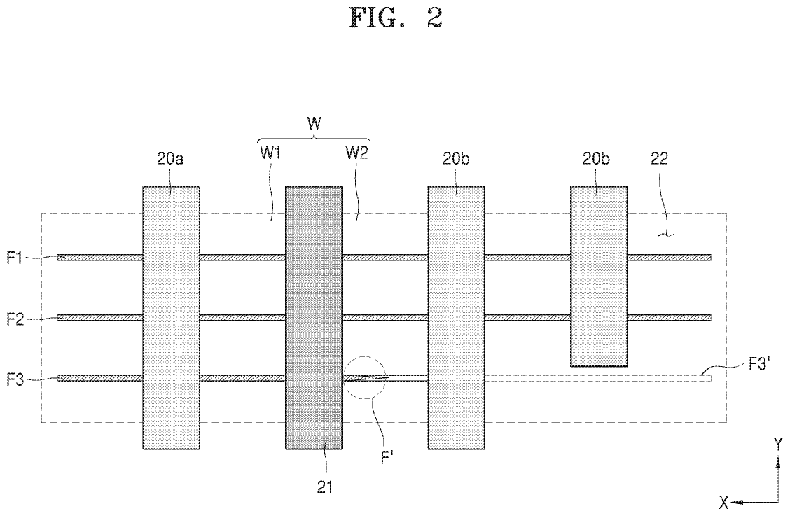

FIGS. 1 to 4B are views illustrating processes of forming a semiconductor device on a substrate.

In detail, FIG. 1 is a view illustrating a process of forming a plurality of fins F1, F2, and F3 on a substrate W.

Referring to FIG. 1, the plurality of fins F1, F2, and F3 may be formed on the substrate W. The number of fins F1, F2, and F3 formed on the substrate W is 3 in FIG. 1. However, the inventive concept is not limited thereto. The number of fins F1, F2, and F3 may vary.

The plurality of fins F1, F2, and F3 may protrude from the substrate W and may extend in a first direction X. A distance by which the plurality of fins F1, F2, and F3 are spaced apart from one another in a second direction Y may be about 10 nm to about 200 nm.

When the plurality of fins F1, F2, and F3 are formed on the substrate W, a process of removing a region F3′ of the fin F3 among the plurality of fins F1, F2, and F3 may be additionally performed. With reference to a cut surface of the fin F3 to be removed, a region of the substrate W in which the fin F3 is not cut off is referred to as a first region W1 and a region of the substrate W in which the fin F3 is cut off is referred to as a second region W2.

By removing a part of the fin F3 to be cut off, the number of fins formed on the first region W1 of the substrate W may be different from the number of fins formed on the second region W2 of the substrate W. Semiconductor devices of various specifications may be formed on the substrate W while forming a varying number of fins on the substrate W. For example, the semiconductor device formed in the first region W1 of the substrate W may include a greater number of fins F1, F2, and F3 than the semiconductor device formed in the second region W2 of the substrate W.

The region F3′ to be removed of the fin F3 to be removed may be removed through a photo etching process. In the photo etching process, when the fin F3 to be removed is normally cut off, the cut surface of the fin F3 may be smooth. However, when the fin F3 to be removed is not normally cut off, a parasitic fin F′ that protrudes from the cut surface of the fin F3 toward the second region W2 may remain.

Referring to FIG. 2, after forming the plurality of fins F1, F2, and F3 and removing the region F3′ of the fin F3, a process of forming an isolation layer 22 that covers at least parts of side walls of the plurality of fins F1, F2, and F3 on the substrate W may be performed. The isolation layer 22 may include a silicon oxide and may be formed by a shallow trench isolation (STI) process.

When the isolation layer 22 is formed on the substrate W, a process of forming first and second gate structures 20a and 20b and a dummy gate structure 21 on the plurality of fins F1, F2, and F3 may be performed. The first gate structure 20a may be formed in the first region W1 of the substrate W to cross the plurality of fins F1, F2, and F3 in the second direction Y. In addition, the second gate structure 20b may be formed in the second region W2 of the substrate W to cross the plurality of fins F1 and F2 in the second direction Y.

The first gate structure 20a formed in the first region W1 of the substrate W may cross a greater number of fins F1, F2, and F3 than the second gate structure 20b formed in the second region W2.

The dummy gate structure 21 may be formed near the cut surface of the fin F3 to cross the plurality of fins F1, F2, and F3 in the second direction Y. The dummy gate structure 21 may be a structure for electrically isolating a semiconductor device to be formed in the first region W1 from semiconductor devices to be formed in the second region W2.

As described above, when the fin F3 to be removed is not normally cut off, the parasitic fin F′ may remain at one side of the dummy gate structure 21.

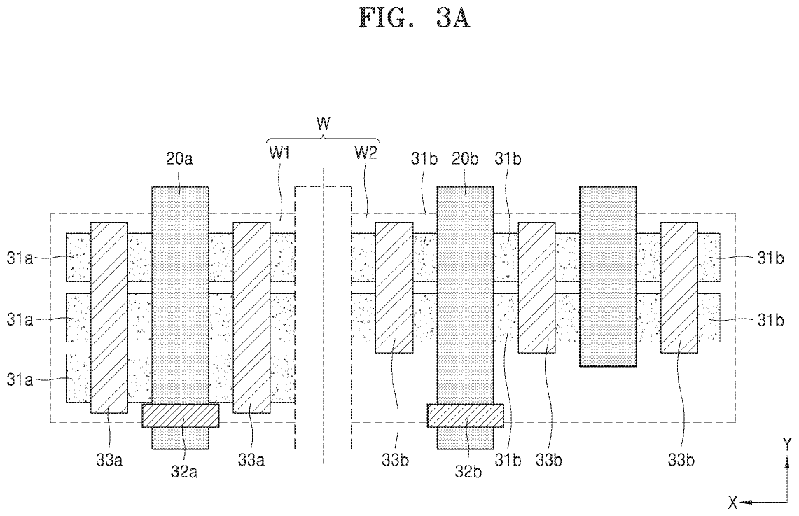

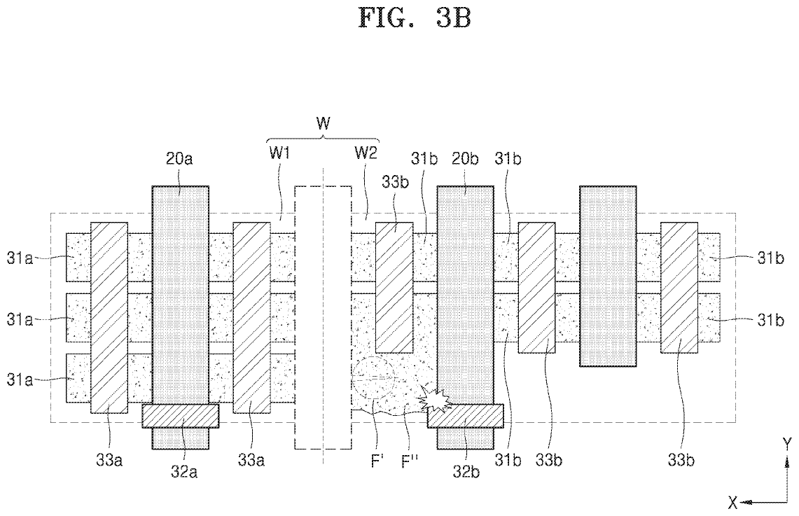

Referring to FIGS. 3A and 3B, after performing a process of forming the first and second gate structures 20a and 20b and the dummy gate structure 21 on the substrate W, a process of forming first source/drains 31a and second source/drains 31b may be performed.

A source may be formed at one side of each of the first and second gate structures 20a and 20b and a drain may be formed at the other side of each of the first and second gate structures 20a and 20b. The source may be spaced apart from the drain by the first and second gate structures 20a and 20b. The first source/drains 31a and the second source/drains 31b may be grown through epitaxial growth.

After forming the first source/drains 31a and the second source/drains 31b, a process of forming first source/drain contacts 33a on the first source/drains 31a and a process of forming second source/drain contacts 33b on the second source/drains 31b may be performed. The first source/drain contacts 33a and the second source/drain contacts 33b extend in the second direction Y and may electrically connect the first source/drains 31a and the second source/drains 31b, respectively. In addition, a process of forming a first gate contact 32a on the first gate structure 20a and a process of forming a second gate contact 32b on the second gate structure 20b may be performed.

The processes of forming a semiconductor device may include a process of removing the dummy gate structure 21. The dummy gate structure 21 may be removed through the photo etching process. Through the photo etching process, the semiconductor device formed in the first region W1 of the substrate W may be electrically isolated from the semiconductor device formed in the second region W2 of the substrate W.

FIG. 3A is a view illustrating a process of forming the first and second source/drains 31a and 31b, the first and second source/drain contacts 33a and 33b, and first and second gate contacts 32a and 32b in a state in which the fin F3 to be cut off is normally cut off. FIG. 3B is a view illustrating a process of forming the first and second source/drains 31a and 31b, the first and second source/drain contacts 33a and 33b, and the first and second gate contacts 32a and 32b in a state in which the fin F3 to be cut off is not normally cut off and accordingly, the parasitic fin F′ remains.

The first and second gate contacts 32a and 32b may surround upper surfaces and side surfaces of the first and second gate structures 20a and 20b. Therefore, when the first and second gate contacts 32a and 32b are seen from above, partial regions of the first and second gate contacts 32a and 32b may be greater than footprints of the first and second gate structures 20a and 20b. However, example embodiments of the inventive concepts are not limited thereto. The first and second gate contacts 32a and 32b may be attached to the upper surfaces of the first and second gate structures 20a and 20b without surrounding the side surfaces of the first and second gate structures 20a and 20b.

Referring to FIG. 3B, in a state in which the first and second gate contacts 32a and 32b surround the upper surfaces and side surfaces of the first and second gate structures 20a and 20b and the parasitic fin F′ remains, when a process of growing the second source/drain 31b is performed, the parasitic fin F′ may also grow with the second source/drain 31b. The grown parasitic fin F″ contacts the neighboring second source/drain contact 33b and a side surface of the second gate contact 32b formed on the neighboring second gate structure 20b and may generate an electrical short. Contact of the grown parasitic fin F″ to the second gate contact 32b and the second source/drain contact 33b may deteriorate the performance of the semiconductor device.

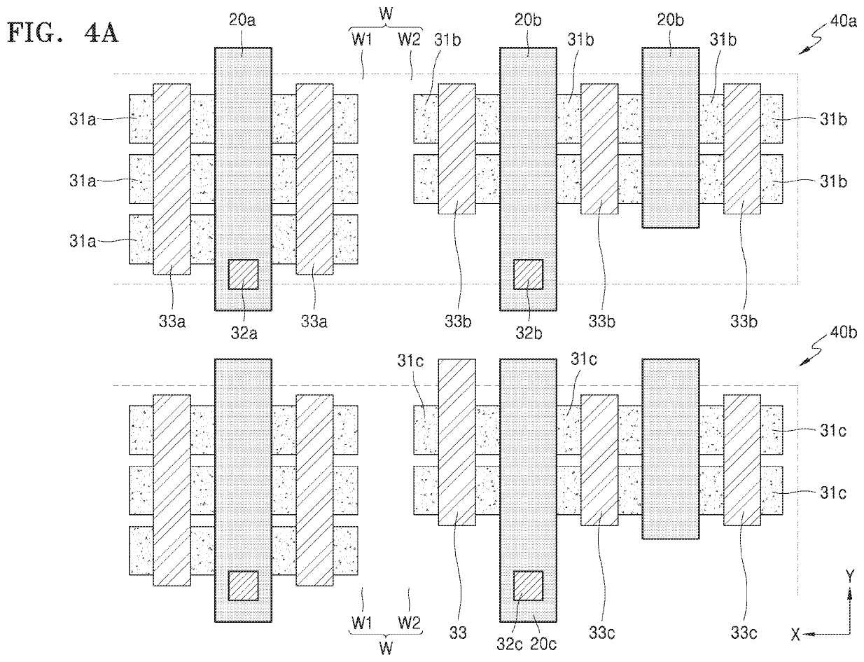

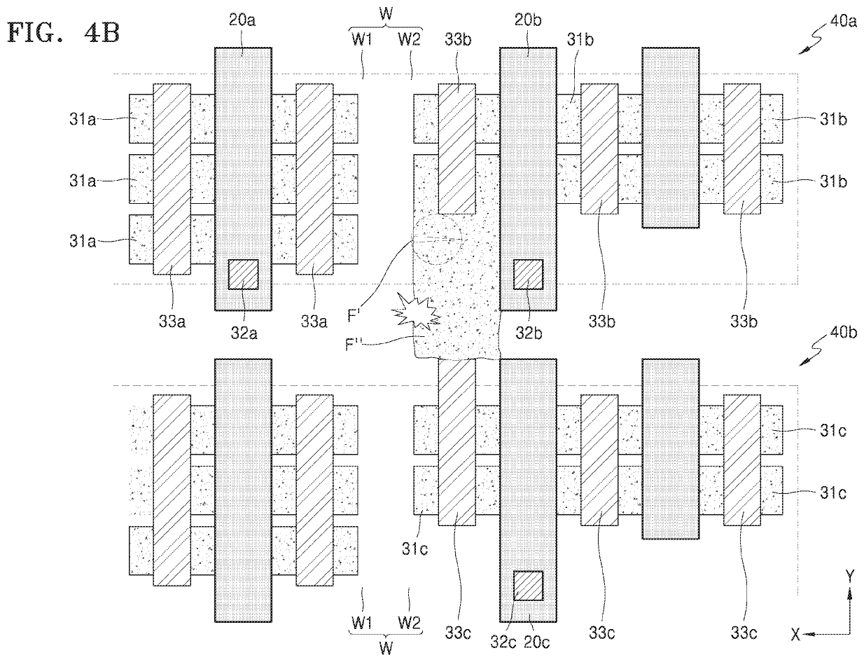

Referring to FIGS. 4A and 4B, a plurality of semiconductor devices may be formed on the substrate W. The semiconductor device formed on the second region W2 of the substrate W is referred to as a first semiconductor device 40a and the semiconductor device formed under the second region W2 of the substrate W is referred to as a second semiconductor device 40b. As described above, the first semiconductor device 40a may include the second source/drain 31b, the second source/drain contact 33b, the second gate structure 20b, and the second gate contact 32b. The second semiconductor device 40b may include a third source/drain 31c, a third source/drain contact 33c, a third gate structure 20c, and a third gate contact 32c. Unlike in FIGS. 3A and 3B, the second gate contact 32b and the third gate contact 32c may be attached to upper surfaces of the second gate structure 20b and the third gate structure 20c.

Referring to FIG. 4A, when the second source/drain 31b is grown in a state in which the region F3′ of the fin F3 to be cut off of the first semiconductor device 40a is normally cut off on the second region W2 of the substrate W, a source/drain may not be formed on a partial side surface (that is, the region F3′ of the removed fin F3) of the second gate structure 20b.

However, referring to FIG. 4B, when the parasitic fin F′ remains on the second region W2 of the substrate W, in a case in which the second source/drain 31b is grown, the parasitic fin F′ may also grow. The grown parasitic fin F″ is electrically connected to the second source/drain contact 33b of the first semiconductor device 40a and the third source/drain contact 33c of the second semiconductor device 40b, electrically connects the first semiconductor device 40a to the second semiconductor device 40b, and may generate an electrical short. Therefore, performances of the first semiconductor device 40a and the second semiconductor device 40b may deteriorate.

Therefore, hereinafter, a test pattern group for addressing (or, alternatively, solving) problems occurring in the above-described processes of forming the semiconductor device and a semiconductor device including the test pattern group will be described in detail.

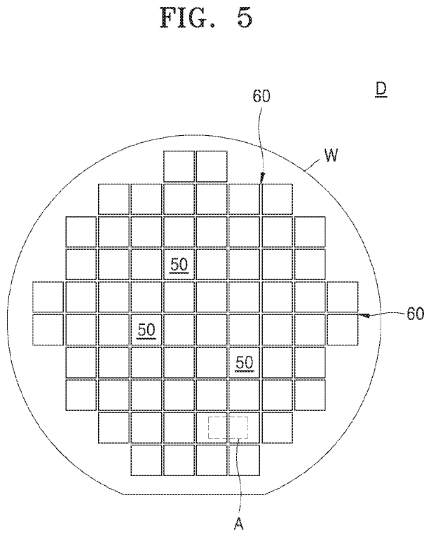

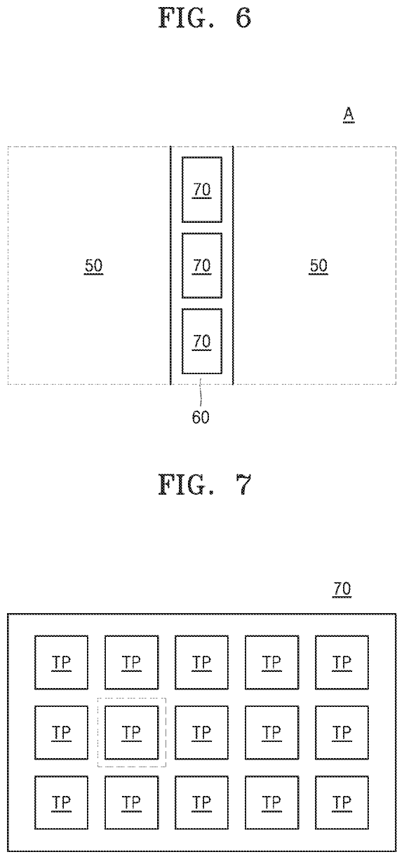

FIG. 5 is a view illustrating a semiconductor device D in which semiconductor devices are integrated according to an example embodiment of the inventive concepts. FIG. 6 is a view illustrating an enlargement of the region A of the semiconductor device D of FIG. 5.

Referring to FIGS. 5 and 6, the semiconductor device D may include the substrate W. Device regions 50 including the semiconductor devices and scribe lanes 60 among the device regions 50 may be formed on the substrate W. The device regions 50 may be two-dimensionally arranged on a front surface of the substrate W and may be surrounded by the scribe lanes 60. That is, the scribe lanes 60 may be arranged among the device regions 50.

The device regions 50 may include a logic device, a memory device, and a control device. In addition, the device regions 50 may include a plurality of Fin-field effect transistor (FET) devices.

Test pattern groups 70 for evaluating electrical characteristics of the semiconductor devices may be provided in the scribe lanes 60. However, example embodiments of the inventive concepts are not limited thereto. The test pattern groups 70 may be provided on a certain portion of the device region 50.

The test pattern groups 70 may include a plurality of test semiconductor devices and a plurality of test pads. The test pads may be electrically connected to the test semiconductor devices through conductive lines.

The test semiconductor devices may have the same structure as the semiconductor devices formed on the device region 50. In an example embodiment, each of the test semiconductor devices may include a plurality of metal-oxide-semiconductor field-effect transistors (MOSFETs).

FIG. 7 is a plan view illustrating an enlargement of a test pattern group 70 according to example embodiments of the inventive concepts.

Referring to FIG. 7, the test pattern group 70 may include a plurality of test patterns TP. The test patterns TP may include one or more semiconductor devices. The test patterns TP may be arranged in a matrix as illustrated in FIG. 7.

The test patterns TP may be tested under various conditions in a process of forming the semiconductor devices on the device region 50 of the substrate W. In an example embodiment, positions and sizes of components of the semiconductor devices formed on the test patterns TP may vary. By performing a plurality of tests using the test patterns TP with the positions and sizes of the components formed on the test patterns TP varying, desired (or, alternatively, ideal) positions and sizes of the components of the semiconductor devices formed on the substrate W may be secured.

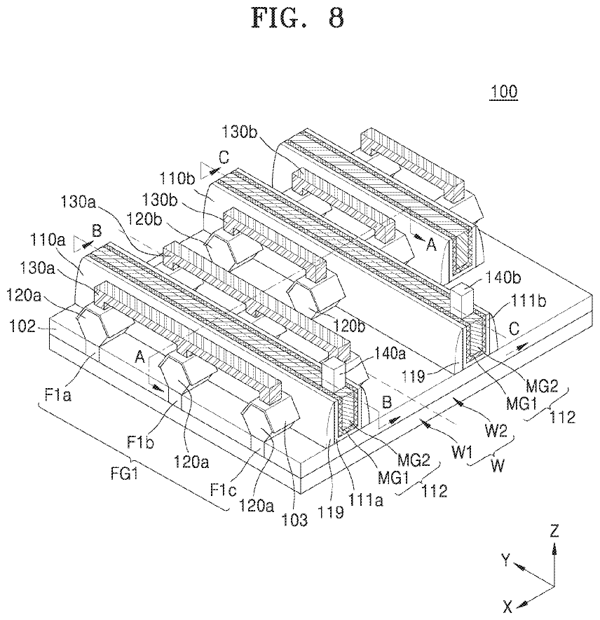

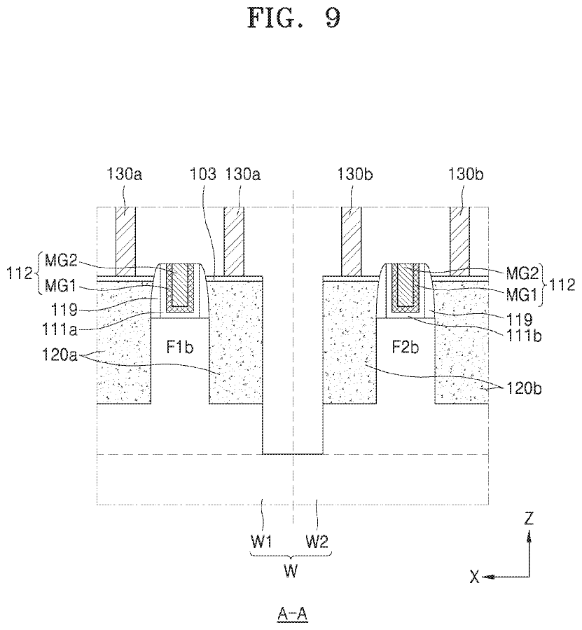

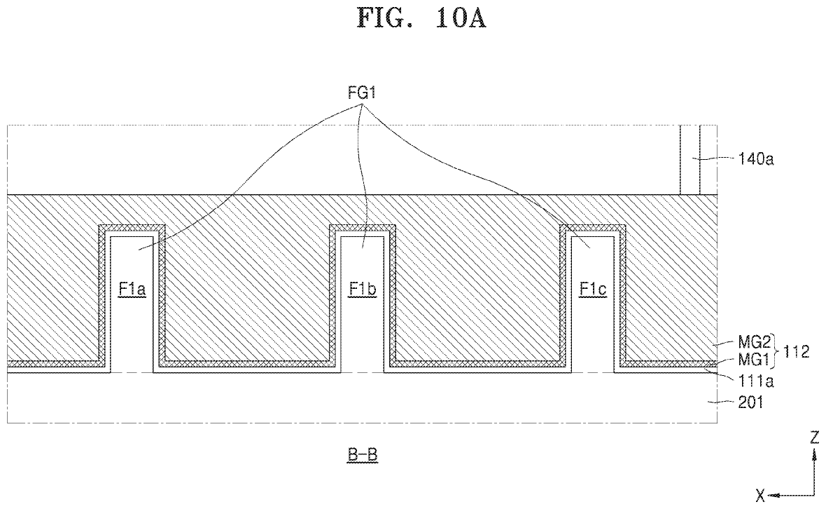

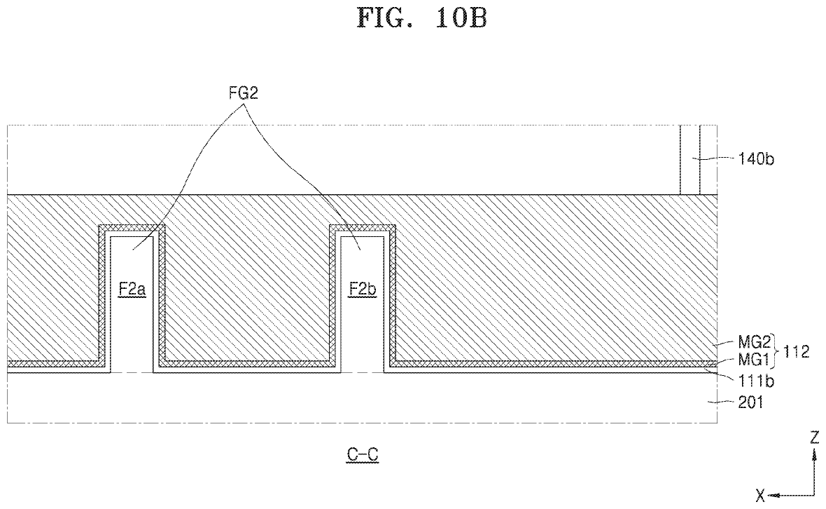

FIG. 8 is a perspective view illustrating a test pattern 100 according to an example embodiment of the inventive concepts. FIG. 9 is a cross-sectional view taken along the line A-A of FIG. 8 of the test pattern 100 according to an example embodiment of the inventive concepts. FIG. 10A is a cross-sectional view taken along the line B-B of FIG. 8 of the test pattern 100 according to an example embodiment of the inventive concepts. FIG. 10B is a cross-sectional view taken along the line C-C of FIG. 8 of the test pattern 100 according to an example embodiment of the inventive concepts.

Referring to FIGS. 8 to 10B, the test pattern 100 of the semiconductor device according to an example embodiment of the inventive concepts may include the substrate W, a first fin group FG1, a second fin group FG2, a first gate structure 110a, a second gate structure 110b, first source/drains 120a, second source/drains 120b, first source/drain contacts 130a, second source/drain contacts 130b, a first gate contact 140a, and a second gate contact 140b.

The substrate W may include various materials. For example, the substrate W may include one of silicon (Si), germanium (Ge), SiGe, GaP, GaAs, SiC, SiGeC, InAs, and InP.

The test pattern 100 may include the first fin group FG1 and the second fin group FG2. The first fin group FG1 may include a plurality of fins F1a, F1b, and F1c formed on the first region W1 of the substrate W. The second fin group FG2 may include a plurality of fins F2a and F2b formed on the second region W2 of the substrate W. The plurality of fins F1a, F1b, and F1c of the first fin group FG1 and the plurality of fins F2a and F2b of the second fin group FG2 are spaced apart from each other in the first direction X and may not be electrically connected.

The number of fins included in the first fin group FG1 of the test pattern 100 according to example embodiments of the inventive concepts may be different from the number of fins included in the second fin group FG2 of the test pattern 100 according to the inventive concept. For example, the first fin group F1 may include a greater number of fins F1a, F1b, and F1c than the second fin group F2. As illustrated in FIG. 1, the first fin group FG1 on the first region W1 of the substrate W may include the three fins F1a, F1b, and F1c and the second fin group FG2 on the second region W2 of the substrate W may include the two fins F2a and F2b. In addition, unlike in FIG. 1, the first fin group FG1 may include four fins and the second fin group FG2 may include only one fin. The number of fins included in the first fin group FG1 and the second fin group FG2 may vary without being limited thereto.

The plurality of fins F1a, F1b, F1c, F2a, and F2b included in the first fin group FG1 and the second fin group FG2 may protrude from the substrate W. That is, the plurality of fins F1a, F1b, F1c, F2a, and F2b may protrude in a third direction Z.

The plurality of fins F1a, F1b, F1c, F2a, and F2b may extend in the first direction X. In more detail, the plurality of fins F1a, F1b, F1c, F2a, and F2b may extend in the first direction X in the form of a rectangular parallelepiped.

An insulating layer 102 may cover at least parts of side walls of the plurality of fins F1a, F1b, F1c, F2a, and F2b.

The first gate structure 110a may be formed on the first fin group FG1 and the second gate structure 110b may be formed on the second fin group FG2. In more detail, the first gate structure 110a may intersect with the plurality of fins F1a, F1b, and F1c included in the first fin group FG1 in the second direction Y and the second gate structure 110b may intersect with the plurality of fins F2a and F2b included in the second fin group FG2 in the second direction Y. The first gate structure 110a may cover side surfaces and upper surfaces of the plurality of fins F1a, F1b, and F1c included in the first fin group FG1. The second gate structure 110b may cover side surfaces and upper surfaces of the plurality of fins F2a and F2b included in the second fin group FG2.

The first gate structure 110a and the second gate structure 110b may include gate insulating layers 111a and 111b and a gate electrode 112.

The gate insulating layer 111a of the first gate structure 110a may be positioned between the plurality of fins F1a, F1b, and F1c on the first region W1 of the substrate W and the gate electrode 112. The gate insulating layer 111b of the second gate structure 110b may be positioned between the plurality of fins F2a and F2b on the second region W2 of the substrate W and the gate electrode 112. As illustrated in FIGS. 10A and 10B, the first and second gate insulating layers 111a and 111b may be formed along the upper surfaces and side surfaces of the plurality of fins F1a, F1b, F1c, F2a, and F2b.

The gate electrode 112 may include a plurality of metal layers MG1 and MG2. The plurality of metal layers MG1 and MG2 may include at least one of TiN, TaN, TiC, TaC, tungsten (W), and aluminium (Al).

Spacers 119 may be arranged on side walls of the first and second gate structures 110a and 110b.

The first source/drains 120a may be formed on side surfaces of the first gate structure 110a and the second source/drains 120b may be formed on side surfaces of the second gate structure 110b. In more detail, a source may be formed at one side of each of the first and second gate structures 110a and 110b and a drain may be formed at the other side of each of the first and second gate structures 110a and 110b. The source and drain may be spaced apart from each other by the first and second gate structures 110a and 110b. The first and second source/drains 120a and 120b may be formed through epitaxial growth. The first and second source/drains 120a and 120b may protrude from the plurality of fins F1a, F1b, F1c, F2a, and F2b to be higher than the plurality of fins F1a, F1b, F1c, F2a, and F2b.

As described above, since the number of fins formed on the first region W1 of the substrate W may be different from the number of fins formed on the second region W2 of the substrate W, the number of first source/drains 120a formed on the side surfaces of the first gate structure 110a on the first region W1 of the substrate W may be different from the number of second source/drains 120b formed on the side surfaces of the second gate structure 110b on the second region W2 of the substrate W. In an example embodiment, a greater number of source/drains may be formed on the side surfaces of the first gate structure 110a on the first region W1 of the substrate W than on the side surfaces of the second gate structure 110b on the second region W2 of the substrate W. For example, as illustrated in FIG. 1, the three fins F1a, F1b, and F1c are formed on the first region W1 of the substrate W and accordingly, the three pairs of first source/drains 120a may be formed on the both side surfaces of the first gate structure 110a and the two fins F2a and F2b are formed on the second region W2 of the substrate W and accordingly, the two pairs of second source/drains 120b may be formed on the both side surfaces of the second gate structure 110b. The number of first and second source/drains 120a and 120b formed on the first and second gate structures 110a and 110b is not limited thereto and may vary.

Referring to FIG. 8, the first and second source/drains 120a and 120b formed at one side of the first and second gate structures 110a and 110b may be spaced apart from each other. However, example embodiments of the inventive concepts are not limited thereto. As fins are arranged on the substrate W by a small distance, the first and second source/drains 120a and 120b may be integrated without being spaced apart from each other.

The first and second source/drains 120a and 120b may have a varying shape. For example, the first and second source/drains 120a and 120b may have at least one shape among a hexagon, a diamond, a circle, and a rectangle.

The first source/drain contacts 130a may be formed on the first source/drains 120a and the second source/drain contacts 130b may be formed on the second source/drains 120b. The first and second source/drain contacts 130a and 130b extend on the first and second source/drains 12a and 120b formed at one side of the first and second gate structures 110a and 110b in the second direction Y and may electrically connect the first and second source/drains 120a and 120b.

Silicide layers 103 may be formed between the first and second source/drains 120a and 120b and the first and second source/drain contacts 130a and 130b. The silicide layers 103 may include a conductive material such as Pi, nickel (Ni), or a cobalt (Co). The silicide layers 103 may reduce contact resistance between the first and second source/drains 120a and 120b and the first and second source/drain contacts 130a and 130b.

The first gate contact 140a may be formed on the first gate structure 110a and the second gate contact 140b may be formed on the second gate structure 110b.

Although not shown in FIGS. 8 to 10B, an interlayer insulating layer may be formed on the substrate W. The interlayer insulating layer exposes the first gate contact 140a, the second gate contact 140b, upper portions of the first source/drain contacts 130a, and upper portions of the second source/drain contacts 130b and may cover the side walls of the first and second gate structures 110a and 110b, the first and second source/drains 120a and 120b, and the first and second source/drain contacts 130a and 130b.

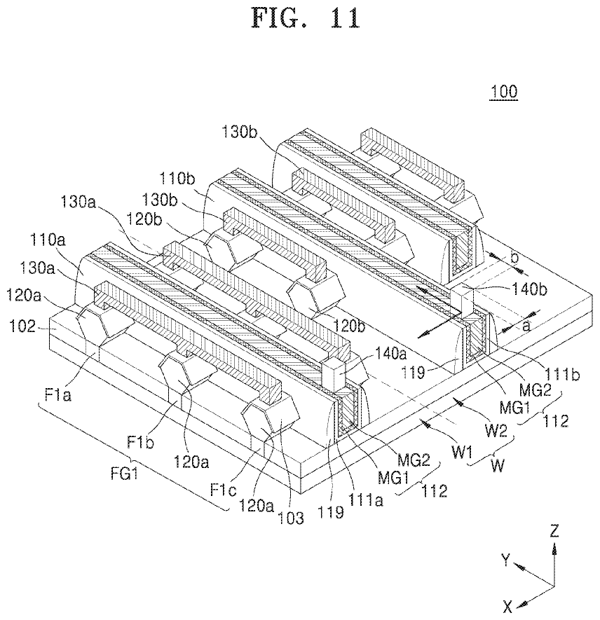

Hereinafter, referring to FIGS. 11 to 13, an electrical test method using the above-described test pattern 100 and the effect of the electrical test will be described in detail.

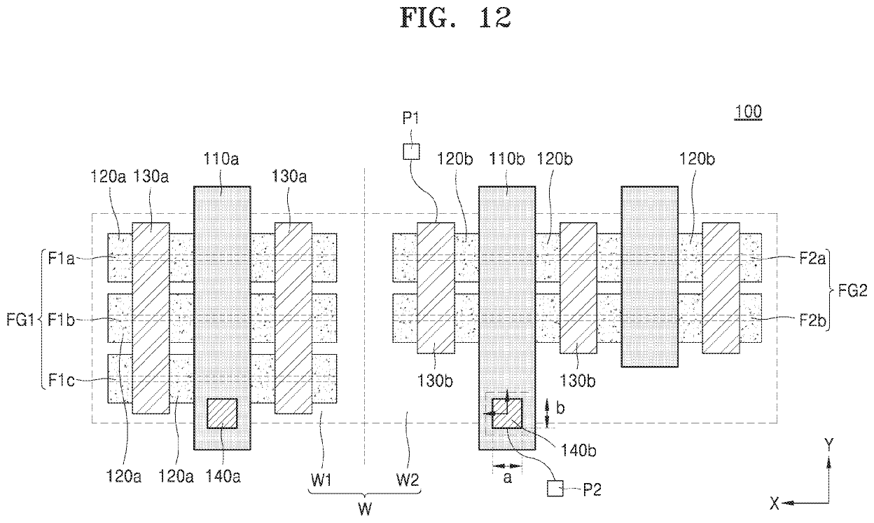

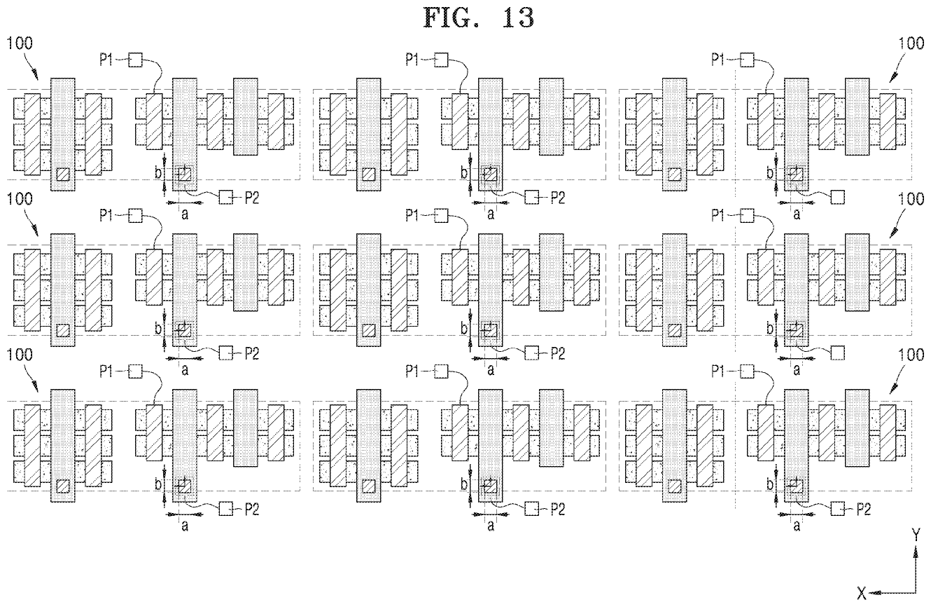

FIG. 11 is a perspective view of the test pattern 100 according to an example embodiment of the inventive concepts. FIG. 12 is a plan view of the test pattern 100 according to an example embodiment of the inventive concepts. FIG. 13 is a plan view of a test pattern group including the test patterns 100 according to an example embodiment of the inventive concepts.

Referring to FIGS. 11 to 13, as described above, the test pattern 100 may include the second gate contact 140b on the second gate structure 110b.

The test pattern group 70 (FIG. 6) may include the test patterns 100. Sizes of the second gate contacts 140b formed on the second gate structures 110b of the second regions W2 of the test patterns 100 may vary.

In an example embodiment, the test patterns 100 may include the second gate contacts 140b with different lengths a in the first direction X. In the first direction X, fins of the second fin group FG2 may extend. In addition, the test patterns 100 may include the second gate contacts 140b with different lengths b in the second direction Y perpendicular to the first direction X.

On the test patterns 100, at least one of the first length a and the second length b of each of the second gate contacts 140b on the second regions W2 may be split in units of about 1 nm to about 100 nm. In an example embodiment, at least one of the first length a and the second length b of each of the second gate contacts 140b may be split in units of about 5 nm. At this time, the test patterns 100 may include the second gate contacts 140b having various first and second lengths a and b of about 5 nm, 10 nm, 15 nm, 20 nm, 25 nm . . . .

On the test patterns 100, after making at least one of the first length a in the first direction X and the second length b in the second direction Y of each of the second gate contacts 140b vary, a test is performed by using the test patterns 100 and accordingly, a desired (or, alternatively, an ideal) size of the second gate contact 140b on the second region W2 may be designed. In more detail, when the parasitic fin F′ remains on the second region W2 of the test pattern 100 and is grown with the second source/drains 120b, the grown parasitic fin F″ contacts the second gate contact 140b on the second gate structure 110b and may generate an electrical short. Therefore, while performing an electrical test with the second gate contact 140b of a varying size formed on the second gate structure 110b in the plurality of test patterns, a desired (or, alternatively, an ideal) size of the second gate contact 140b, in which the grown parasitic fin F″ does not contact the second gate contact 140b on the second gate structure 110b, may be found.

The electrical test may be performed by using a first pad P1 and a second pad P2. The first pad P1 may be electrically connected to the second source/drain contacts 130b on the second region W2 and the second pad P2 may be electrically connected to the second gate contact 140b on the second region W2. In more detail, the first pad P1 may be electrically connected to the second source/drain contacts 130b on the second region W2 closest to the first region W1 of the test pattern 100 and the second pad P2 may be electrically connected to the second gate contact 140b on the second region W2 closest to the first region W1 of the test pattern 100.

When the first pad P1 and the second pad P2 are connected to each other, the electrical test may be performed with a voltage applied to the first pad P1.

As described above, in a case in which the parasitic fin F′ is grown with the second source/drains 120b and the grown parasitic fin F″ is electrically connected to the second gate contact 140b, when the voltage is applied to the first pad P1, a current may be detected from the second pad P2.

Therefore, the test pattern group 70 (FIG. 6) according to an example embodiment of the inventive concepts may include the test patterns 100. As described above, the test patterns 100 may include the second gate contacts 140b of various sizes on the second gate structures 110b on the second region W2. While performing the electrical test of the test patterns 100, a desired (or, alternatively, an ideal) size of the second gate contact 140b on the second gate structure 110b of the second region W2, in which it is possible to inhibit (or, alternatively, prevent) an electrical short from being generated between the grown parasitic fin F″ and the second gate contact 140b, may be found. In the test pattern 100, after finding the desired (or, alternatively, ideal) size of the second gate contact 140b on the second gate structure 110b, a process of forming the second gate contact 140b on the device region 50 of the semiconductor device W is performed and accordingly, the flexibility of processes of producing the semiconductor device may increase.

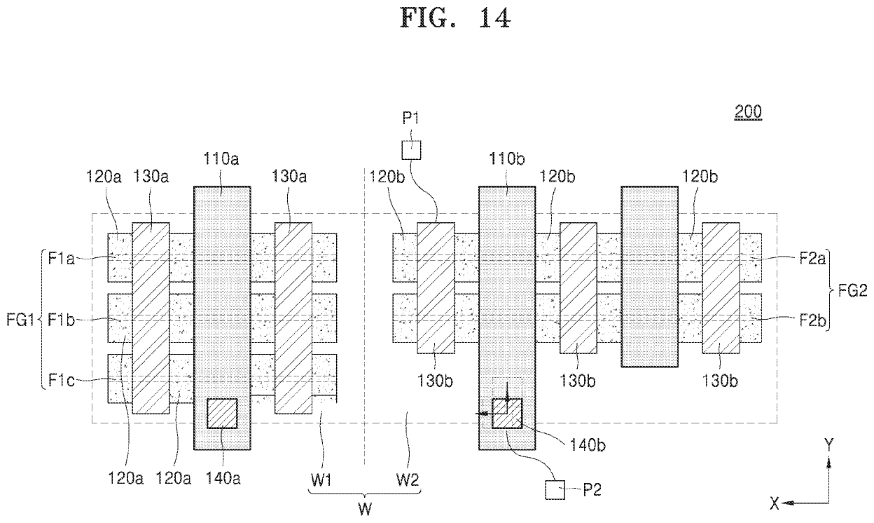

FIG. 14 is a plan view of a test pattern 200 according to an example embodiment of the inventive concepts.

Referring to FIG. 14, a position of the second gate contact 140b formed on the second gate structure 110b of the second region W2 of the test pattern 200 may vary.

For example, the test pattern 200 may include the second gate contacts 140b of different positions in the first direction X. The fins may extend in the first direction X. In addition, the test pattern 200 may include the second gate contacts 140b of different positions in the second direction Y perpendicular to the first direction X. In this case, sizes of the second gate contacts 140b included in the test pattern 200 may be actually the same.

On the test pattern 200, a test is performed with at least one of the positions of the second gate contacts 140b in the first direction X and the positions of the second gate contacts 140b in the second direction Y varying and accordingly, a desired (or, alternatively, an ideal) position of the second gate contact 140b may be designed. After performing the test, a process of forming the second gate contact 140b on the device region 50 of the semiconductor device is performed and accordingly, the flexibility of processes of producing the semiconductor device may increase.

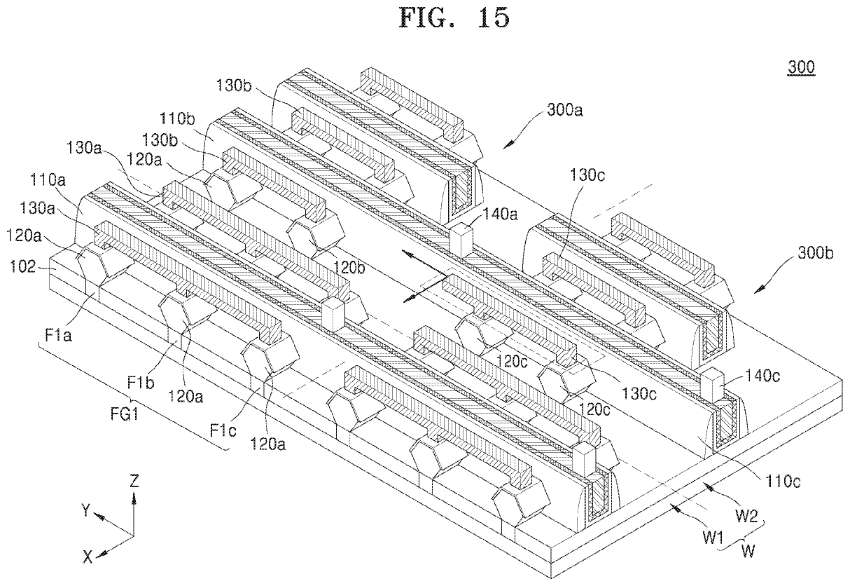

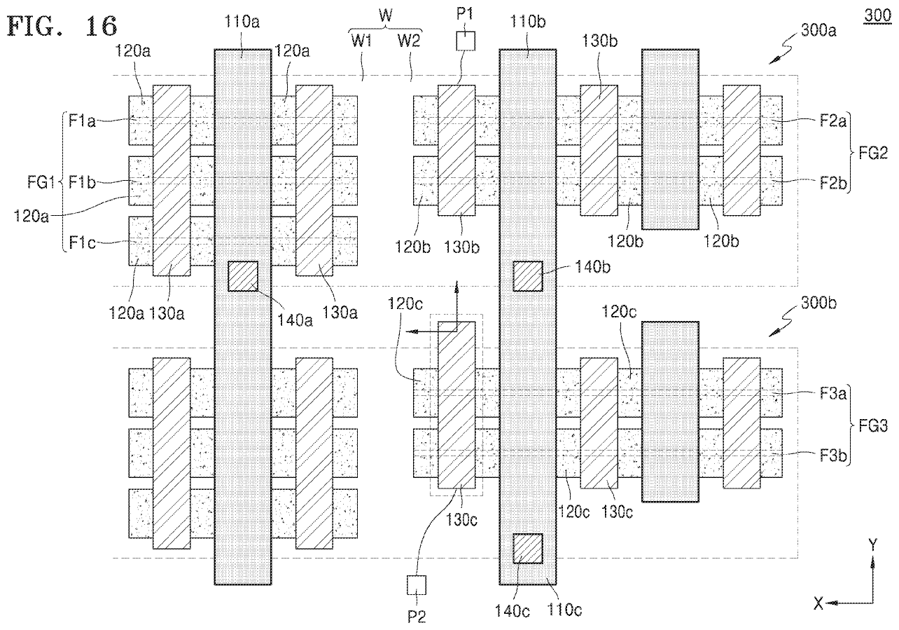

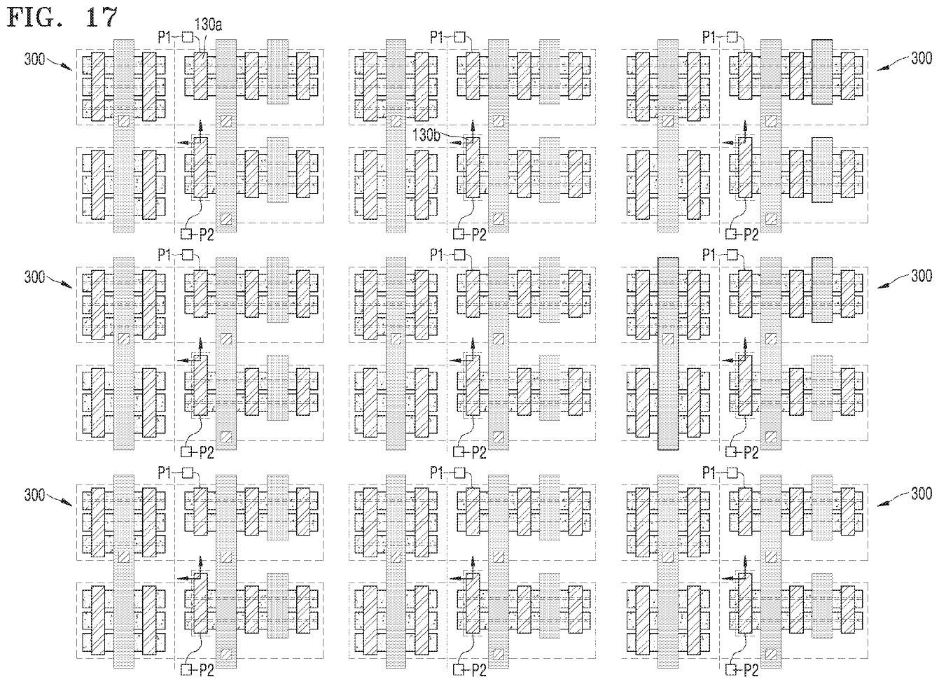

FIG. 15 is a perspective view of a test pattern 300 according to an example embodiment of the inventive concepts. FIG. 16 is a plan view of the test pattern 300 according to an example embodiment of the inventive concepts. FIG. 17 is a plan view of a test pattern group including the plurality of test pattern 300 according to an example embodiment of the inventive concepts.

Referring to FIGS. 15 to 17, the test pattern 300 according to some example embodiments of the inventive concepts may include a first test pattern 300a and a second test pattern 300b.

In the test pattern 300, the test pattern positioned in an upper portion is referred to as the first test pattern 300a. In the test pattern 300, the test pattern positioned in a lower portion is referred to as the second test pattern 300b.

The first test pattern 300a may include the first fin group FG1, the second fin group FG2, the first gate structure 110a on the first region W1, the second gate structure 110b on the second region W2, the first source/drains 120a, the second source/drains 120b, the first gate contact 140a, the second gate contact 140b, the first source/drain contacts 130a, and the second source/drain contacts 130b.

The second test pattern 300b may include a third fin group FG3, a third gate structure 110c, third source/drains 120c, a third gate contact 140c, and third source/drain contacts 130c.

Since components of the first test pattern 300a and the second test pattern 300b are actually the same as the spirit described with reference to FIGS. 8 to 10, detailed description thereof will not be given.

Positions of the third source/drain contacts 130c formed on the second region W2 of the substrate W of the second test pattern 300b and closest to the first region W1 may vary on the test pattern 300.

For example, the test pattern 300 may include the third source/drain contacts 130c with different positions in the first direction X. Fins may extend in the first direction X. In addition, the test pattern 300 may include the third source/drain contacts 130c with different positions in the second direction Y perpendicular to the first direction X.

On the test pattern 300, the positions of the third source/drain contacts 130c in the first direction X and the positions of the third source/drain contacts 130c in the second direction Y may be split in units of about 1 nm to about 100 nm. In an example embodiment, the positions of the third source/drain contacts 130c in the first direction X and the positions of the third source/drain contacts 130c in the second direction Y may be split in units of about 5 nm.

On the test pattern 300, by making at least one of the positions of the third source/drain contacts 130c on the second test pattern 300b in the first direction X and the positions of the third source/drain contacts 130c on the second test pattern 300b in the second direction Y vary, desired (or, alternatively, ideal) positions of the third source/drain contacts 130c may be designed.

As described above, when the parasitic fin F′ remains and is grown on the second region W2 of the first test pattern 300a of the test pattern 300, an electrical short may be generated between the grown parasitic fin F″ and the third source/drain contacts 130c on the second region W2 of the second test pattern 300b. Therefore, the desired (or, alternatively, the ideal) positions of the third source/drain contacts 130c may be designed through an electrical test using the test pattern 300.

The electrical test may be performed by using the first pad P1 and the second pad P2. The first pad P1 may be electrically connected to the second source/drain contacts 130b on the second region W2 of the first test pattern 300a. The second pad P2 may be electrically connected to the third source/drain contacts 130c on the second region W2 of the second test pattern 300b. In more detail, the first pad P1 may be electrically connected to the second source/drain contacts 130b on the second region W2 closest to the first region W1 of the first test pattern 300a and the second pad P2 may be electrically connected to the third source/drain contacts 130c on the second region W2 closest to the first region W1 in the second test pattern 300b. Connection between the first pad P1 and the second pad P2 is not limited thereto. The first pad P1 and the second pad P2 may be connected in a varying position in which it is possible to check whether an electrical short is generated between the grown parasitic fin F″ and the third source/drain contacts 130c of the second test pattern 300b.

When the first pad P1 and the second pad P2 are connected to each other, an electrical test may be performed with a voltage applied to the first pad P1. The parasitic fin F″ grown with the second source/drains 120b may be electrically connected to the third source/drain contacts 130c of the second test pattern 300b. In this case, when the voltage is applied to the first pad P1, a current may be detected from the second pad P2.

By the above-described electrical test method, on the test pattern 300, the desired (or, alternatively, ideal) positions of the third source/drain contacts 130c of the second test pattern 300b may be designed. After performing the electrical test, a process of forming the third source/drain contacts 130c on the device region 50 of the semiconductor device W is performed and accordingly, the flexibility of processes of producing the semiconductor device may increase.

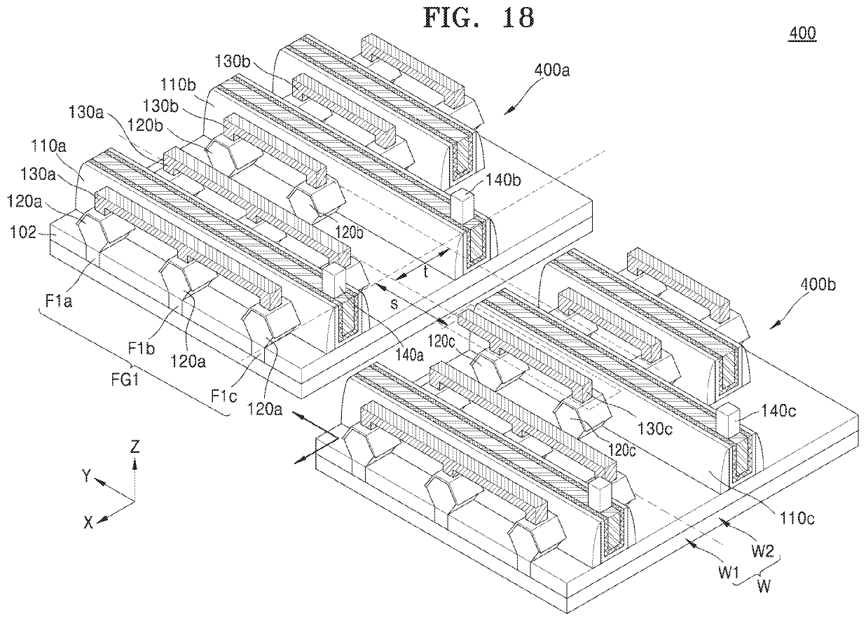

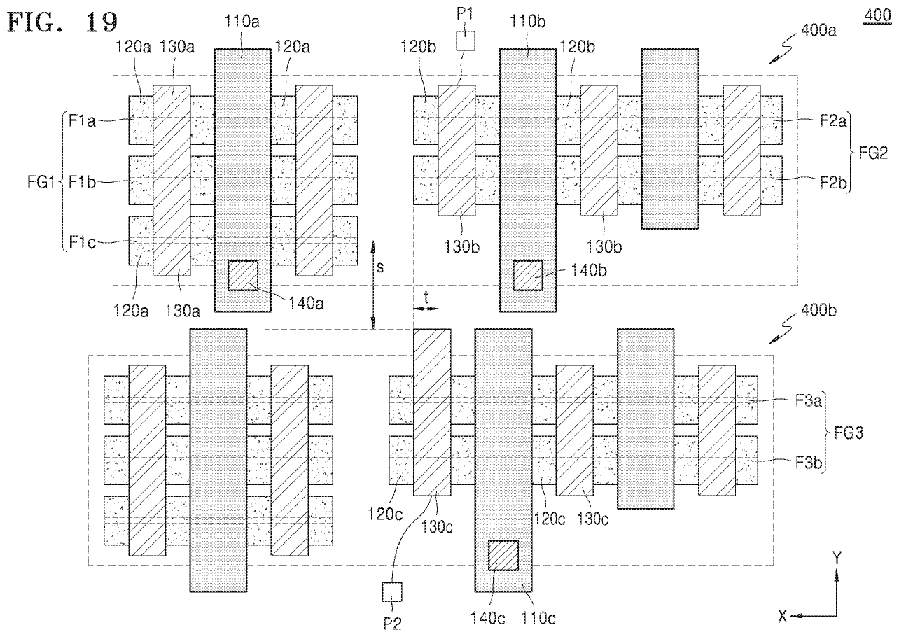

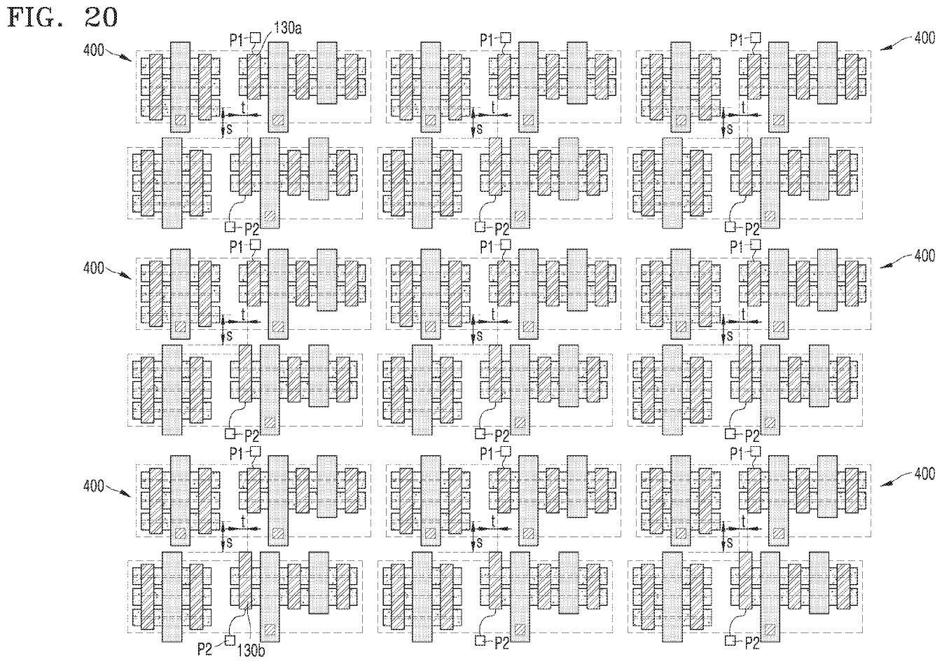

FIG. 18 is a perspective view of a test pattern 400 according to an example embodiment of the inventive concepts. FIG. 19 is a plan view of the test pattern 400 according to an example embodiment of the inventive concepts. FIG. 20 is a plan view of a test pattern group including test patterns 400 according to an example embodiment of the inventive concepts.

Referring to FIGS. 18 to 20, the test pattern 400 according to the inventive concept may include a first test pattern 400a and a second test pattern 400b.

The first test pattern 400a may include the first fin group FG1, the second fin group FG2, the first gate structure 110a, the second gate structure 110b, the first source/drains 120a, the second source/drains 120b, the first source/drain contacts 130a, the second source/drain contacts 130b, the first gate contact 140a, and the second gate contact 140b.

The second test pattern 400b may include the third fin group FG3, the third gate structure 110c, the third source/drains 120c, the third source/drain contacts 130c, and the third gate contact 140c.

Since components of the first test pattern 400a and the second test pattern 400b are actually the same as the spirit described with reference to FIGS. 8 to 10, detailed description thereof will not be given.

As illustrated in FIG. 18, the third gate structure 110c, the third source/drains 120c, the third source/drain contacts 130c, and the third gate contact 140c that are the components of the second test pattern 400b may not be aligned with the second gate structure 110b, the second source/drains 120b, the second source/drain contacts 130b, and the second gate contact 140b and may be misaligned with the second gate structure 110b, the second source/drains 120b, the second source/drain contacts 130b, and the second gate contact 140b.

For example, the third source/drain contacts 130c of the second test pattern 400b may be misaligned with the second source/drain contacts 130b of the first test pattern 400a in the first direction X. In more detail, the third source/drain contacts 130c closest to the first region W1 on the second test pattern 400b may be misaligned with the second source/drain contacts 130b closest to the first region W1 on the first test pattern 400a.

On the test patterns 400, a distance t by which the components of the first test pattern 400a are misaligned with the components of the second test pattern 400b in the first direction X may vary. Fins may extend in the first direction X.

On the test patterns 400, the distance t by which the components of the first test pattern 400a are misaligned with the components of the second test pattern 400b may be split in units of about 1 nm to about 100 nm. In an example embodiment, the distance t by which the components of the first test pattern 400a are misaligned with the components of the second test pattern 400b may be split in units of about 5 nm. Therefore, the test pattern group may include the test patterns 400 having various distances t such as about 5 nm, 10 nm, 15 nm, 20 nm, 25 nm . . . .

In addition, on the test patterns 400, a distance s by which a fin F1c positioned in a lowermost portion of the first test pattern 400a is spaced apart from the third source/drain contacts 130c of the second test pattern 400b in the second direction Y may vary among the test patterns 400. The second direction Y is perpendicular to the first direction X. That is, in the second direction Y, a gate structure may extend.

On the test patterns 400, the distance s by which a fin F1c positioned in a lowermost portion of the first test pattern 400a is spaced apart from the third source/drain contacts 130c of the second test pattern 400b in the second direction Y may be split in units of about 1 nm to about 100 nm. In an example embodiment, the distance s by which a fin F1c positioned in a lowermost portion of the first test pattern 400a is spaced apart from the third source/drain contacts 130c of the second test pattern 400b in the second direction Y may be split in units of about 5 nm. Therefore, the test pattern group may include the test patterns 400 having various distances s such as about 5 nm, 10 nm, 15 nm, 20 nm, 25 nm . . . .

On the test patterns 400, an electrical test may be performed while misaligning the components of the second test pattern 400b with the components of the first test pattern 400a in the first direction X or making the distance s by which the third source/drain contacts 130c of the second test pattern 400b are spaced apart from the fin F1c positioned in the lowermost portion of the first test pattern 400a in the second direction Y vary.

The first pad P1 and the second pad P2 may be used for the electrical test. The first pad P1 may be electrically connected to the second source/drain contacts 130b on the second region W2 closest to the first region W1 in the first test pattern 400a. The second pad P2 may be electrically connected to the third source/drain contacts 130c on the second region W2 closest to the first region W1 in the second test pattern 400b.

Connection between the first pad P1 and the second pad P2 is not limited thereto. The first pad P1 and the second pad P2 may be connected in a varying position in which it is possible to check whether an electrical short is generated between the grown parasitic fin F″ and the third source/drain contacts 130c of the second test pattern 300b.

When the first pad P1 and the second pad P2 are connected to each other, an electrical test may be performed with a voltage applied to the first pad P1. In a case in which the parasitic fin F′ is grown with the second source/drains 120b and the grown parasitic fin F″ is electrically connected to the third source/drain contacts 130c of the second test pattern 400b, when the voltage is applied to the first pad P1, a current may be detected from the second pad P2.

While performing the electrical test a plurality of times, the desired (or, alternatively, ideal) distance t by which the components of the first test pattern 400a are misaligned with the components of the second test pattern 400b in the first direction X may be designed. In addition, while performing the electrical test a plurality of times, the desired (or, alternatively, ideal) distance s by which the fin F1c positioned in the lowermost portion of the first test pattern 400a is spaced apart from the third source/drain contacts 130c of the second test pattern 400b in the second direction Y may be designed. After performing the electrical test, the semiconductor devices are formed on the device region 50 of the semiconductor device W and accordingly, the flexibility of processes of producing the semiconductor devices may increase.

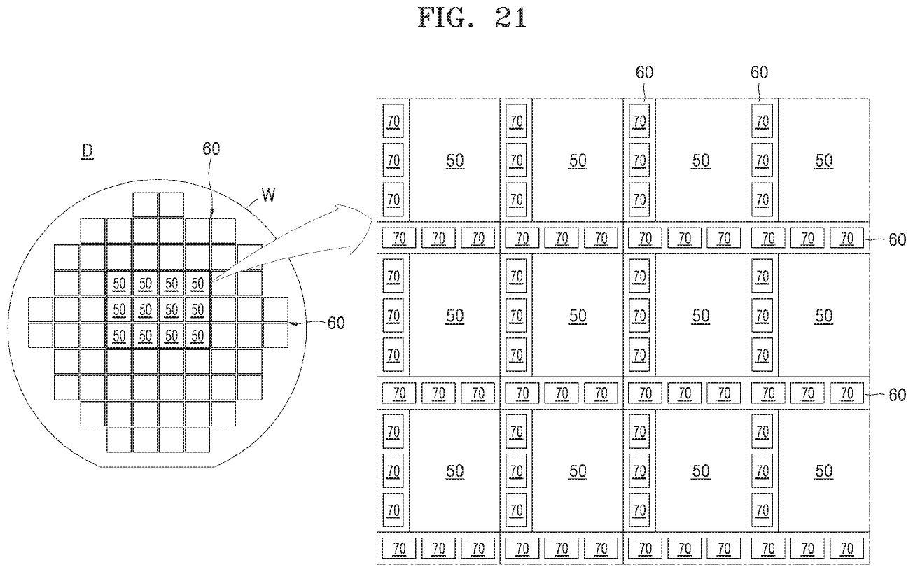

FIG. 21 is a view illustrating a semiconductor device D including a test pattern according to an example embodiment of the inventive concepts.

The semiconductor device D according to example embodiments of the inventive concepts may include the substrate W, the device regions 50 in which the semiconductor devices are formed, and the scribe lanes 60 among the device regions 50. The test pattern group 70 may be formed on the scribe lanes 60. The test pattern group 70 may include the above-described test patterns 100, 200, 300, and 400.

Since the spirit of the test patterns 100, 200, 300, and 400 is actually the same as the descriptions given above with reference to FIGS. 8 to 20, detailed description thereof will not be given.

While example embodiments of the inventive concepts have been particularly shown and described with reference to embodiments thereof, it will be understood that various changes in form and details may be made therein without departing from the spirit and scope of the following claims.

What is claimed is:

1. A test pattern group comprising:
a plurality of test patterns, each of the plurality of test patterns including,
a substrate including a first region and a second region,
a first fin group including first fins extending on the first region of the substrate,
a second fin group including second fins extending on the second region of the substrate, a number of the second fins of the second fin group less than a number of first fins of the first fin group,
a first gate structure on the first fin group such that the first gate structure intersects the first fins of the first fin group,
a second gate structure on the second fin group such that the second gate structure intersects the second fins of the second fin group,
a first source/drain at a side portion of the first gate structure,
a second source/drain at a side portion of the second gate structure,
a first source/drain contact on the first source/drain,
a second source/drain contact on the second source/drain,
a first gate contact on the first gate structure, and
a second gate contact on the second gate structure.

2. The test pattern group of claim 1, wherein the first fin group and the second fin group are on the substrate such that the first fin group is not electrically connected to the second fin group.

3. The test pattern group of claim 1, wherein the plurality of test patterns each include the second gate structure such that sizes of the second gate contact on the second gate structure vary amongst the plurality of test patterns.

4. The test pattern group of claim 3, wherein the plurality of test patterns each include the second gate structure such that, in a first direction, first lengths of the second gate contact on the second gate structure vary amongst the plurality of test patterns, the first direction being a direction in which the second fins of the second fin group extend.

5. The test pattern group of claim 4, wherein the plurality of test patterns each include the second gate structure such that, in the first direction, the first lengths of the second gate contact on the second gate structure vary in increments of 1 nm to 100 nm.

6. The test pattern group of claim 4, wherein the plurality of test patterns each include the second gate structure such that the first lengths of the second gate contact on the second gate structure in the first direction are different from second lengths of the second gate contact on the second gate structure in a second direction, the second direction being perpendicular to the first direction.

7. The test pattern group of claim 6, wherein the plurality of test patterns each include the second gate structure such that, in the second direction, the second lengths of the second gate contact on the second gate structure vary in increments of 1 nm to 100 nm.

8. The test pattern group of claim 1, wherein the plurality of test patterns each include the second gate structure such that a position of the second gate contact on the second gate structure vary amongst the plurality of test patterns.

9. The test pattern group of claim 8, wherein the plurality of test patterns each include the second gate structure such that the position of the second gate contact on the second gate structure vary amongst the plurality of test patterns in at least one of a first direction and a second direction, the first direction being a direction in which the second fins of the second fin group extend and the second direction being perpendicular to the first direction.

10. A test pattern group comprising:
a plurality of test patterns, each of the plurality of test patterns including,
a first test pattern including,
a substrate including a first region and a second region,
a first fin group including first fins extending on the first region of the substrate,
a second fin group including second fins that extend on the second region of the substrate, a number of the second fins of the second fin group less than a number of the first fins of the first fin group, and the second fins of the second fin group electrically disconnected from the first fins of the first fin group,
a first gate structure on the first fin group such that the first gate structure intersects the first fins of the first fin group,
a second gate structure on the second fin group such that the second gate structure intersects the second fins of the second fin group,
a first source/drain at a side portion of the first gate structure,
a second source/drain at a side portion of the second gate structure,
a first source/drain contact on the first source/drain,
a second source/drain contact on the second source/drain,
a first gate contact on the first gate structure, and
a second gate contact on the second gate structure; and
a second test pattern under the first test pattern, the second test pattern including,
a third fin group including third fins extending on the substrate,
a third gate structure on the third fin group such that the third gate structure intersects with the third fins of the third fin group,
a third source/drain at a side portion of the third gate structure, and
a third source/drain contact on the third source/drain.

11. The test pattern group of claim 10, wherein the plurality of test patterns each include the third source/drain contact such that a position of the third source/drain contacts of the second test pattern vary amongst the plurality of test patterns.

12. The test pattern group of claim 11, wherein the plurality of test patterns each include the third source/drain contact such that the position of the third source/drain contacts of the second test pattern vary in at least one of a first direction and a second direction, and the first direction being a direction in which the second fins of the second fin group extend and the second direction being perpendicular to the first direction.

13. The test pattern group of claim 12, wherein the plurality of test patterns each include the third source/drain contact such that, in the at least one of the first direction and the second direction, the position of the third source/drain contacts of the second test pattern formed on the plurality of test patterns vary in increments of 1 nm to 100 nm.

14. The test pattern group of claim 10, the plurality of test patterns each include the third source/drain contact and the second source/drain contact such that, on the plurality of test patterns, the third source/drain contacts of the second test pattern are misaligned with the second source/drain contacts of the first test pattern in a first direction by a distance, the first direction being a direction in which the second fins of the second fin group extend.

15. The test pattern group of claim 14, wherein the plurality of test patterns each include the third source/drain contact and the second source/drain contact such the distance that the second source/drain contact is misaligned with the third source/drain contact vary in increments of 1 nm to 100 nm.

16. The test pattern group of claim 10, wherein the plurality of test patterns each include the third source/drain contact and the first fins such that, on the plurality of test patterns, a distance by which a lowermost one of the first fins of the first fin group of the first test pattern is apart from the third source/drain contact of the second test pattern varies.

17. The test pattern group of claim 16, wherein the plurality of test patterns each include the third source/drain contact and the first fins such that the distance by which the lowermost one of the first fins is apart from the third source/drain contact varies in increments of 1 nm to 100 nm.

18. A semiconductor device comprising:
device regions having semiconductor devices therein;
scribe lanes surrounding the device regions; and
a test pattern group on the scribe lanes, the test pattern group including a plurality of test patterns, each of the plurality of test patterns including,
a substrate including a first region and a second region;
a first fin group including first fins extending on the first region of the substrate;
a second fin group including second fins extending on the second region of the substrate, a number of the second fins of the second fin group less than a number of the first fins of the first fin group, and the second fins of the second fin group electrically disconnected from the first fins of the first fin group;
a first gate structure on the first fin group such that the first gate structure intersects with the first fins of the first fin group;
a second gate structure on the second fin group such that the second gate structure intersects with the second fins of the second fin group;
a first source/drain at a side portion of the first gate structure;
a second source/drain at a side portion of the second gate structure;
a first source/drain contact on the first source/drain;
a second source/drain contact on the second source/drain;
a first gate contact on the first gate structure; and
a second gate contact on the second gate structure.

19. The semiconductor device of claim 18, wherein the plurality of test patterns are on the scribe lanes.

20. The semiconductor device of claim 18, wherein the plurality of test patterns each include the second gate structure such that at least one of sizes and positions of the second gate contact on the second gate structure varies amongst the plurality of test patterns.
